(19) United States
(12) Patent Application Publication
(10) Pub. No.: US 2010/0091251 A1
(43) Pub. Date: Apr. 15, 2010

(54) HEAT DISSIPATING DEVICE FOR ELECTRONIC APPARATUS, AND ELECTRONIC APPARATUS

(76) Inventors: Hiroko FUJIBAYASHI, Aichi (JP); Daiki Fujiwara, Shizuoka (JP); Hiroyuki Meguro, Shizuoka (JP); Noriyuki Hagino, Aichi (JP)

Correspondence Address: FROMMER LAWRENCE & HAUG LLP, 745 FIFTH AVENUE, NEW YORK, NY, 10151, US

(21) Appl. No.: 12/633,018

(22) Filed: Dec. 8, 2009

(30) Foreign Application Priority Data
Oct. 12, 2008 (JP) P2008-314444

(51) Int. Cl. G03B 21/16; H05K 7/20

(52) U.S. Cl. 353/56; 361/714

(57) ABSTRACT

A heat dissipating device for an electronic apparatus includes an enclosure that houses a component of the electronic apparatus which becomes hot when the electronic apparatus is in use, the enclosure being made of a heat conductive material capable of dissipating heat in the enclosure to the outside, a heat receiving member provided between the component and the enclosure and capable of receiving heat from the component and transferring the received heat, a heat insulating member provided in contact with a side of the heat receiving member opposite from the component and configured to prevent transmission of the heat received by the heat receiving member, and a heat diffusing member provided between the heat insulating member and the enclosure in contact with both the heat insulating member and the enclosure and capable of receiving heat from the heat insulating member and diffusing the received heat into the enclosure.

### BACKGROUND OF THE INVENTION

1. Field of the Invention

The present invention relates to a heat dissipating device for use in an electronic apparatus such as a projection display apparatus which projects light to produce an image on a screen or the like, and the electronic apparatus. More particularly, the present invention relates to a technique enabling reduction in the thickness and size of an electronic apparatus while preventing a local increase in temperature of an enclosure of the electronic apparatus.

2. Description of the Related Art

Electronic apparatuses include projection display apparatuses such as a liquid crystal projector. A projection display apparatus is provided with a light source such as a lamp unit supported by a reflector, a light valve configured to modulate light emitted from the light source, and a projection lens configured to project an image obtained by irradiating the light valve with light. The image projected from the projection lens is thrown onto a screen or the like.

When the projection display apparatus is in use, various components of the apparatus (particularly, the lamp unit) become hot, and the temperature inside the enclosure of the apparatus increases. An exhaust fan is used to exhaust the high-temperature air to the outside of the enclosure so as to keep each component within its guaranteed operating temperature range. In order to prevent the enclosure from locally having a high temperature in the proximity of the lamp unit, it is common practice to provide a lamp cover surrounding the lamp unit, a heat dissipating member arranged outside the lamp cover at a distance from the lamp cover, and a heat receiving section attached to the lamp cover to receive heat generated by the lamp unit, so as to transmit the heat received by the heat receiving section to the heat dissipating member via a heat conduction member (see, e.g., Japanese Unexamined Patent Application Publication No. 2006-91697).

### SUMMARY OF THE INVENTION

With the above-described technique of the related art, heat generated by the lamp unit is dissipated by the heat dissipating member which is arranged outside the lamp cover along the cover. With this technique, although it may be possible to reduce the thickness of the projection display apparatus, space for arranging the heat dissipating member alongside the lamp cover is necessary, which leads to an increased size of the apparatus in the width direction, hindering reduction of the size of the apparatus.

In view of the foregoing, it is desirable to provide a technique which enables reduction in the thickness as well as the size of an electronic apparatus such as a projection display apparatus, while preventing an enclosure of the electronic apparatus from locally having a high temperature.

According to an embodiment of the present invention, there is provided a heat dissipating device for an electronic apparatus, the heat dissipating device including: an enclosure configured to house a component of an electronic apparatus, the component becoming hot when the electronic apparatus is in use, the enclosure being made of a heat conductive material capable of dissipating heat in the enclosure to the outside; a heat receiving member provided between the component and the enclosure and capable of receiving heat from the component and transferring the received heat; a heat insulating member provided in contact with a side of the heat receiving member opposite from the component, the heat insulating member being configured to prevent transmission of the heat received by the heat receiving member; and a heat diffusing member provided between the heat insulating member and the enclosure so as to contact both the heat insulating member and the enclosure, the heat diffusing member being capable of receiving heat from the heat insulating member and diffusing the received heat into the enclosure.

According to another embodiment of the present invention, there is provided an electronic apparatus including: a component which becomes hot when in use; an enclosure configured to house the component, the enclosure being made of a heat conductive material capable of dissipating heat in the enclosure to the outside; a heat receiving member provided between the component and the enclosure and capable of receiving heat from the component and transferring the received heat; a heat insulating member provided in contact with a side of the heat receiving member opposite from the component, the heat insulating member being configured to prevent transmission of the heat received by the heat receiving member; and a heat diffusing member provided between the heat insulating member and the enclosure so as to contact both the heat insulating member and the enclosure, the heat diffusing member being capable of receiving heat from the heat insulating member and diffusing the received heat into the enclosure.

In the embodiments of the present invention described above, the heat receiving member receives heat from the component within the enclosure, and the heat insulating member prevents transmission of the heat. While heat inevitably accumulates in the heat insulating member, heat may not be fully absorbed by the heat insulating member. Thus, the heat diffusing member is configured to cause the heat that had not been absorbed by the heat insulating member to be diffused widely over the enclosure. In this manner, the heat inside the apparatus is transmitted to the enclosure while being diffused, and finally dissipated to the outside.

According to the above embodiments of the present invention, heat from a component within the apparatus is diffused widely into the enclosure, which can prevent a local temperature increase of the enclosure. The heat is dissipated from the enclosure to the outside. This means that the enclosure itself serves as a heat dissipating member, and thus, it is unnecessary to additionally provide a heat dissipating member as in the above-described technique of the related art. Accordingly, it is possible to reduce both the thickness and size of the electronic apparatus, while preventing the enclosure of the apparatus from locally having a high temperature.

### BRIEF DESCRIPTION OF THE DRAWINGS

FIG. 1 is a perspective view showing an internal structure of a liquid crystal projector as an embodiment of an electronic apparatus of the present invention;

FIG. 2 is a plan view showing the internal structure of the liquid crystal projector as the embodiment of the electronic apparatus of the present invention;

FIG. 3 is a plan view showing an internal structure of an optical unit included in the liquid crystal projector shown in FIGS. 1 and 2;

FIG. 4A is a cross sectional view of a heat dissipating device provided in a liquid crystal projector according to an embodiment of the present invention, and FIG. 4B is a thermal distribution diagram corresponding thereto;

FIG. 5A is a cross sectional view of a heat dissipating device provided in a liquid crystal projector of a comparative example 1, and FIG. 5B is a thermal distribution diagram corresponding thereto;

FIG. 6A is a cross sectional view of a heat dissipating device provided in a liquid crystal projector of a comparative example 2, and FIG. 6B is a thermal distribution diagram corresponding thereto;

FIG. 7A is a cross sectional view of a heat dissipating device provided in a liquid crystal projector of a comparative example 3, and FIG. 7B is a thermal distribution diagram corresponding thereto;

FIG. 8A is a cross sectional view of a heat dissipating device provided in a liquid crystal projector of a comparative example 4, and FIG. 8B is a thermal distribution diagram corresponding thereto; and

FIG. 9A is a cross sectional view of a heat dissipating device provided in a liquid crystal projector of a comparative example 5, and FIG. 9B is a thermal distribution diagram corresponding thereto.

### DESCRIPTION OF THE PREFERRED EMBODIMENTS

A best mode for carrying out the present invention (hereinafter, referred to as an “embodiment”) will now be described with reference to the drawings.

In the following, a liquid crystal projector 10, which is a projection display apparatus, will be described as an embodiment of the electronic apparatus of the present invention. Further, in the following, an embodiment of the heat dissipating device of the present invention is provided in the liquid crystal projector 10.

[Configuration Example of Electronic Apparatus (Liquid Crystal Projector 10)]

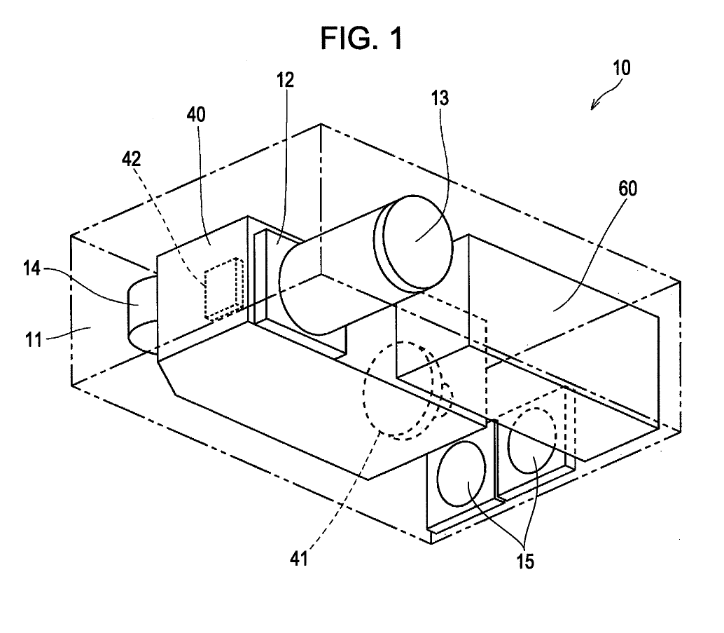

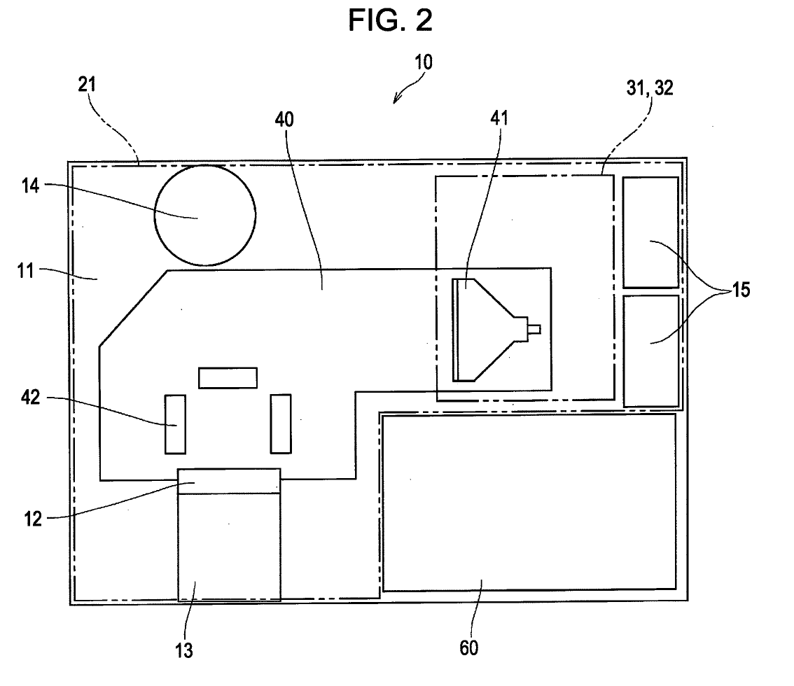

FIGS. 1 and 2 are a perspective view and a plan view, respectively, showing an internal structure of a liquid crystal projector 10 as an embodiment of the electronic apparatus of the present invention.

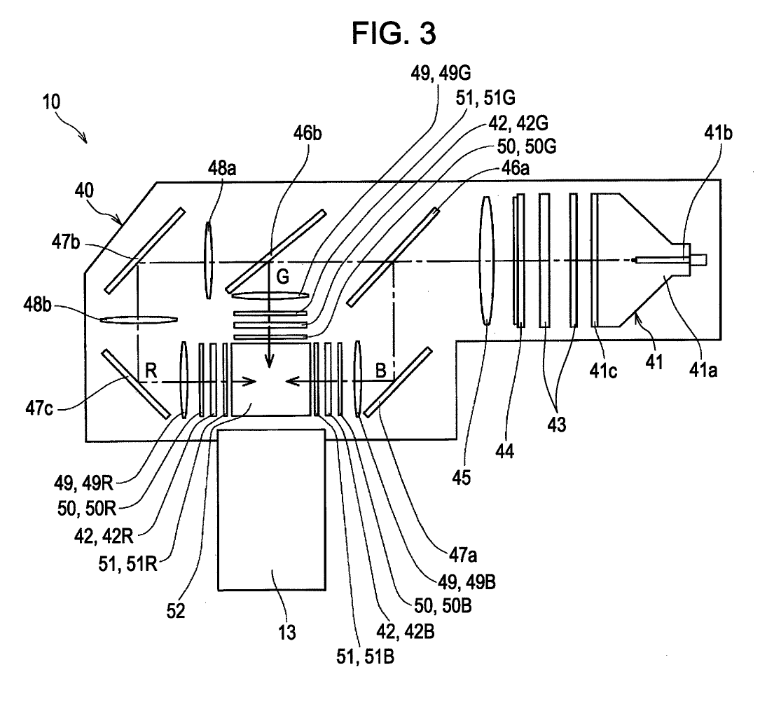

FIG. 3 is a plan view showing an internal structure of an optical unit 40 which is included in the liquid crystal projector 10 shown in FIGS. 1 and 2.

A heat dissipating device according to an embodiment of the present invention is provided in the liquid crystal projector 10.

Referring to FIGS. 1 and 2, the liquid crystal projector 10 includes an optical unit 40 and a power supply unit 60 housed in a rectangular-parallelepiped magnesium enclosure 11 (corresponding to the “enclosure” of the present invention). The optical unit 40 primarily includes a lamp unit 41 which emits light for projecting an image, and a light valve 42 which modulates the light emitted from the lamp unit 41. Further, a lens holding frame 12 for holding a projection lens 13 which projects an image is attached to a side surface of the optical unit 40 located near the light valve 42. The lens holding frame 12 holds the projection lens 13 in such a manner that an end of the projection lens 13 protrudes from a side surface of the magnesium enclosure 11. With this configuration, an image which has been obtained by irradiating the light valve 42 with the light emitted from the lamp unit 41 is projected onto a screen or the like through the projection lens 13.

Referring now to FIG. 3, the optical unit 40 includes, in addition to the lamp unit 41 and the light valve 42 (including light valves 42R, 42G, and 42B), a fly-eye lens 43, a PS conversion element 44, a condenser lens 45, dichroic mirrors 46a and 46b, total reflection mirrors 47a, 47b, and 47c, relay lenses 48a and 48b, a field lens 49 (including field lenses 49R, 49G, and 49B), an incident-side polarizing plate 50 (including incident-side polarizing plates 50R, 50G, and 50B), an emitting-side polarizing plate 51 (including emitting-side polarizing plates 51R, 51G, and 51B), and a cross prism 52. The light valves 42R, 42G, and 42B modulate light in the wavelength range of red (R), light in the wavelength range of green (G), and light in the wavelength range of blue (B), respectively, of the light emitted from the lamp unit 41. The field lens 49, the incident-side polarizing plate 50, and the emitting-side polarizing plate 51 are provided for each of the light valves 42R, 42G, and 42B.

The optical components provided in the optical unit 40 will now be described in the order of arrangement from the light-emitting side. The lamp unit 41 is primarily made up of a discharge lamp 41b attached to a reflector 41a. Protective glass 41c is also arranged at an aperture of the reflector 41a. The light emitted from the discharge lamp 41b is reflected by the reflector 41a, and is emitted through the protective glass 41c. The discharge lamp 41b may be, e.g., a metal halide lamp, a high pressure mercury lamp, a halogen lamp, or a xenon lamp.

Two fly-eye lenses 43 are arranged at positions distant from the lamp unit 41. The fly-eye lenses 43 receive light from the lamp unit 41, the light having certain intensity distribution, and separate the light into a large number of light spots so as to achieve uniform luminance distribution over the entire surface of the light valve 42 (including the light valves 42R, 42G, and 42B).

Next to the fly-eye lenses 43, the PS conversion element 44 and the condenser lens 45 are arranged in this order. The PS conversion element 44 is composed of polarization beam splitters and phase difference plates. The polarization beam splitters are formed by pieces of strip-shaped glass which are coated with a dielectric film and adhered to each other by an adhesive, and the phase difference plates are intermittently provided so as to correspond to the beam splitters. The PS conversion element 44 serves to convert (or align) the polarization directions of the light from the lamp unit 41.

The dichroic mirrors 46a and 46b are arranged on an opposite side of the condenser lens 45 from the PS conversion element 44. The dichroic mirror 46a is arranged at a predetermined distance from the condenser lens 45, and the dichroic mirror 46b is arranged at a predetermined distance from the dichroic mirror 46a. The dichroic mirrors 46a and 46b are tilted by 45 degrees in the same direction. Of the light which has passed through the condenser lens 45, only light in the wavelength range of blue (B) is reflected by 90 degrees by the dichroic mirror 46a. Of the light which has passed through the dichroic mirror 46a, light in the wavelength range of green (G) is reflected by 90 degrees by the dichroic mirror 46b. The light in the wavelength range of blue (B) which has been reflected by the dichroic mirror 46a is reflected again by 90 degrees by the total reflection mirror 47a which is arranged at a distance from the dichroic mirror 46a.

Accordingly, of the light which has passed through the condenser lens 45, only light in the wavelength range of red (R) goes straight, without being reflected by the dichroic mirror 46a or 46b. On the backside of the dichroic mirror 46b, the relay lens 48a and the total reflection mirror 47b are arranged at a distance from each other, and the light in the wavelength range of red (R) is reflected by 90 degrees by the total reflection mirror 47b. Further, the light in the wavelength range of red (R) passes through the relay lens 48b which is arranged at a distance from the total reflection mirror 47b, and is reflected again by 90 degrees by the total reflection mirror 47c arranged at a distance from the relay lens 48b.

In this manner, the light in the wavelength range of red (R), the light in the wavelength range of green (G), and the light in the wavelength range of blue (B) are separated by the dichroic mirrors 46a and 46b. The light in the wavelength range of blue (B) which has been reflected by the total reflection mirror 47a enters the field lens 49B which is arranged at a distance from the total reflection mirror 47a. The light in the wavelength range of green (G) which has been reflected by the dichroic mirror 46b enters the field lens 49G. The light in the wavelength range of red (R) which has been reflected by the total reflection mirror 47c enters the field lens 49R.

On the emitting sides of the field lenses 49R, 49G, and 49B, the incident-side polarizing plates 50R, 50G, and 50B, respectively, are arranged, at a distance from each other. The light in the wavelength ranges of red (R), green (G), and blue (B), which has entered the corresponding field lenses 49R, 49G, and 49B, passes through the corresponding incident-side polarizing plates 50R, 50G, and 50B, to attain predetermined polarization directions.

The light valves 42R, 42G, and 42B, which are light modulation elements, are arranged to face the incident-side polarizing plates 50R, 50G, and 50B, respectively, with spaces provided therebetween. At each of the light valves 42R, 42G, and 42B, the polarization plane of light is rotated in accordance with an applied image signal. The emitting-side polarizing plates 51R, 51G, and 51B are arranged spaced apart from the light valves 42R, 42G, and 42B, respectively. Of the light whose polarization plane has been rotated, predetermined polarized components pass through a corresponding one of the emitting-side polarizing plates 51R, 51G, and 51B, to constitute a light beam for an image. The light beam for an image enters a corresponding incidence plane of the cross prism 52 (one of three side surfaces other than the side surface on which the projection lens 13 is arranged). The light beams which have entered the cross prism 52 are combined and emitted from the projection lens 13, whereby an image in full color is projected onto a screen or the like.

As described above, the light emitted from the lamp unit 41 is converted into light for an image by the light valves 42R, 42G, and 42B, and other components, before being emitted from the projection lens 13. In projecting an image, the lamp unit 41, the light valves 42R, 42G, and 42B, and other components are heated. It is thus necessary to cool down the components so as to keep each component within its guaranteed operating temperature range.

To this end, as shown in FIGS. 1 and 2, a cooling fan 14 is arranged at the back of the optical unit 40 to generate airflow for cooling the light valve 42 and other components. Further, two exhaust fans 15 are arranged on the side surface of the magnesium enclosure 11. With the airflow from the cooling fan 14, the light valve 42 and the other components in the optical unit 40 are each kept within its guaranteed operating temperature range. Further, the two exhaust fans 15 discharge the hot air within the magnesium enclosure 11 to the outside.

The lamp unit 41 which generates heat becomes particularly hot, attaining a temperature of about 1,000° C. With a recent demand for brighter display images, lamp units generate increasingly greater power. Thus, providing only the exhaust fans 15 is insufficient to prevent the magnesium enclosure 11 from locally becoming hot in the proximity of the lamp unit 41. Moreover, when the liquid crystal projector 10 is reduced in thickness, the lamp unit 41 is arranged immediately inside the magnesium enclosure 11, causing the magnesium enclosure 11 to attain an even higher temperature. For reduction in size of the liquid crystal projector 10, however, it is undesirable to simply add a heat dissipating member.

In view of the foregoing, according to the liquid crystal projector 10 of the present embodiment, as shown in FIG. 2, a graphite sheet 21 (corresponding to the “heat diffusing member” of the present invention) is attached to substantially the entire area of the inner surface of the magnesium enclosure 11 in a close contact manner. Further, in the area close to the lamp unit 41, melamine foam 31 (corresponding to the “heat insulating member” of the present invention) is attached to the inner surface of the graphite sheet 21 in a close contact manner. Still further, aluminum sheet metal 32 (corresponding to the “heat receiving member” of the present invention) having a size identical to that of the melamine foam 31 is attached to the inner surface of the melamine foam 31, again in a close contact manner.

[Configuration Example Of Heat Dissipating Device]

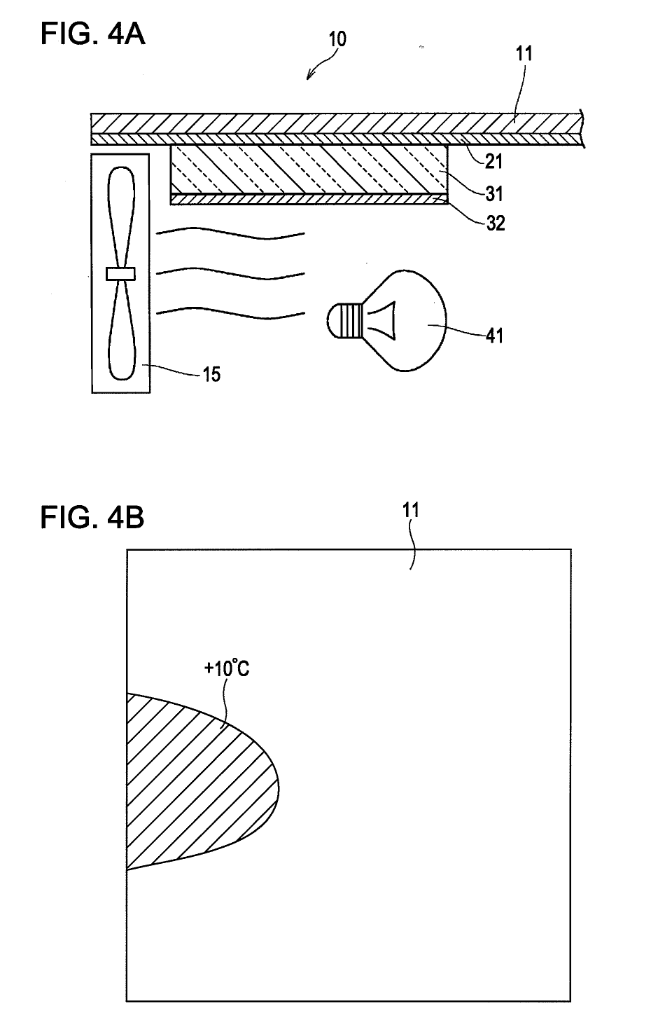

FIG. 4A is a cross sectional view showing a heat dissipating device (made up of the magnesium enclosure 11, the graphite sheet 21, the melamine foam 31, and the aluminum sheet metal 32) provided in the liquid crystal projector 10 according to an embodiment of the present invention, and FIG. 4B is a thermal distribution diagram corresponding thereto.

As shown in FIG. 4A, the lamp unit 41, which becomes hot when the liquid crystal projector 10 is in use, is housed in the magnesium enclosure 11, and the exhaust fan 15 is attached to the magnesium enclosure 11 to face the rear side of the lamp unit 41.

The magnesium enclosure 11 is made of a heat conductive material (magnesium or magnesium alloy) which is capable of dissipating heat in the enclosure to the outside. The magnesium enclosure 11 may have a thickness of 1.2 mm. For the enclosure 11, not only magnesium or magnesium alloy, but also copper, copper alloy, aluminum, aluminum alloy, or any other metal or metal alloy superior in terms of thermal conductivity may be used.

On the inner surface of the magnesium enclosure 11, the flat graphite sheet 21 having a thickness of, e.g., 0.5 mm is attached. The graphite sheet 21 is provided for diffusing the heat over the entirety of the magnesium enclosure 11. To this end, as shown in FIG. 2, the graphite sheet 21 is fixedly secured to almost the entire area of the inner surface of the magnesium enclosure 11 in a close contact manner by adhesion, screwing, welding, or the like. The graphite sheet may be replaced with an aluminum sheet, a copper sheet, or any other sheet superior in terms of thermal conductivity. For fixedly securing the graphite sheet 21, an adhesive having good thermal conductivity is desirably used. The graphite sheet 21 does not necessarily have to be entirely in contact with the magnesium enclosure 11. The graphite sheet 21 may be partially in contact with the magnesium enclosure 11, as long as it can diffuse the heat into the magnesium enclosure 11.

Furthermore, on the inner surface of the graphite sheet 21, within the range facing the lamp unit 41, the flat melamine foam 31 having a thickness of, e.g., 2.0 mm is attached. The melamine foam 31 is a heat insulating member which prevents transmission of heat from the lamp unit 41 to the graphite sheet 21. The melamine foam 31 is fixedly secured to the graphite sheet 21 in a close contact manner by adhesion, welding, or the like. The melamine foam may be replaced with another heat-insulating material, for example hard or soft polyurethane foam, phenolic foam, polystyrene foam, glass wool, rock wool, or microcellular polymer sheet (“PORON” (registered trademark) manufactured by Rogers-INOAC Corporation).

Still further, on the inner surface of the melamine foam 31, within the range facing the lamp unit 41, the flat aluminum sheet metal 32 having a thickness of, e.g., 0.5 mm and having a size identical to that of the melamine foam 31 is attached. The aluminum sheet metal 32 is provided between the lamp unit 41 and the magnesium enclosure 11, at a distance of, e.g., 3.0 mm from the lamp unit 41, and serves to receive heat from the lamp unit 41 and transfer the received heat. The aluminum sheet metal 32 is fixedly secured to the melamine foam 31 in a close contact manner by adhesion, welding, or the like. The aluminum sheet metal may be replaced with copper sheet metal or any other material having good thermal conductivity.

As described above, the heat dissipating device according to the embodiment of the present invention shown in FIG. 4 has a sandwich structure with the melamine foam 31 (heat insulating member) sandwiched between the aluminum sheet metal 32 (heat receiving member having good thermal conductivity) and the graphite sheet 21 (heat diffusing member having good thermal conductivity). Accordingly, heat generated in the lamp unit 41 is transmitted to the aluminum sheet metal 32 which faces the lamp unit 41, via the air between the lamp unit 41 and the aluminum sheet metal 32. The heat received by the aluminum sheet metal 32 spreads over the entirety of the aluminum sheet metal 32. As a result, the aluminum sheet metal 32 becomes entirely hot.

On the opposite side of the aluminum sheet metal 32 from the lamp unit 41, however, the melamine foam 31 having a thickness greater than that of the aluminum sheet metal 32 and that of the graphite sheet 21 is arranged in contact with the aluminum sheet metal 32. This melamine foam 31 prevents transmission of heat from the aluminum sheet metal 32.

As the melamine foam 31 is arranged in contact with the aluminum sheet metal 32 and to face the lamp unit 41, the melamine foam 31 also becomes entirely hot (i.e., heat is accumulated within the melamine foam 31). The heat that has not been absorbed by the melamine foam 31 is transmitted to the graphite sheet 21 which is arranged between the melamine foam 31 and the magnesium enclosure 11 to contact both the melamine foam 31 and the magnesium enclosure 11.

The graphite sheet 21 is provided over a range wider than the aluminum sheet metal 32 and the melamine foam 31, to cover almost the entire area of the inner surface of the magnesium enclosure 11. Thus, heat received by the graphite sheet 21 from the melamine foam 31 is diffused into the entirety of the magnesium enclosure 11 and, then, dissipated from the magnesium enclosure 11 to the outside.

As described above, the graphite sheet 21 prevents heat within the magnesium enclosure 11 (local heat generated in the lamp unit 41) from being built up locally; it allows the heat to be dissipated from the entirety of the magnesium enclosure 11 to the outside. Further, the exhaust fan 15 serves to exhaust the air increased in temperature between the lamp unit 41 and the aluminum sheet metal 32 to the outside of the magnesium enclosure 11. As a result, even in the case where the magnesium enclosure 11 is reduced in thickness as well as in size, the magnesium enclosure 11 is prevented from locally having a high temperature. Specifically, as shown in FIG. 4B, a local temperature increase of the magnesium enclosure 11 is restricted to within 10° C.

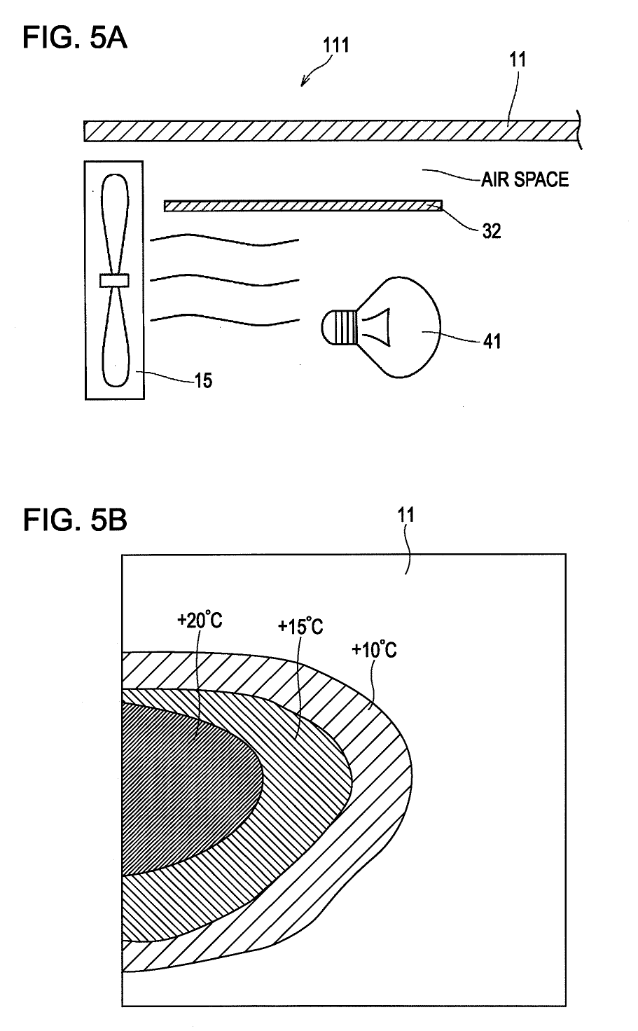

FIG. 5A is a cross sectional view of a heat dissipating device (made up of a magnesium enclosure 11 and aluminum sheet metal 32) provided in a liquid crystal projector 111 of a comparative example 1, and FIG. 5B is a thermal distribution diagram corresponding thereto.

As shown in FIG. 5A, the liquid crystal projector 111 of the comparative example 1 includes a lamp unit 41, the aluminum sheet metal 32, the magnesium enclosure 11, and an exhaust fan 15, which are identical to those included in the liquid crystal projector 10 of the embodiment of the present invention shown in FIG. 4A.

The liquid crystal projector 111 of the comparative example 1 shown in FIG. 5A, however, fails to include the melamine foam 31 and the graphite sheet 21 included in the liquid crystal projector 10 of the embodiment of the present invention shown in FIG. 4A. In the liquid crystal projector 111 of the comparative example 1, there is an air space in place of the melamine foam 31 and the graphite sheet 21 (i.e., between the aluminum sheet metal 32 and the magnesium enclosure 11).

With the liquid crystal projector 111 of the comparative example 1 having the above-described structure, heat generated in the lamp unit 41 is transmitted to the air space between the aluminum sheet metal 32 and the magnesium enclosure 11. The air space on the inner side of the magnesium enclosure 11 becomes locally hot, and the heat is transmitted to the magnesium enclosure 11. As a result, the magnesium enclosure 11 suffers a local temperature increase of 20° C. or more, as shown in FIG. 5B. Accordingly, it can be said that the sandwich structure made up of the aluminum sheet metal 32, the melamine foam 31, and the graphite sheet 21, with no air space included, as in the liquid crystal projector 10 of the embodiment of the present invention shown in FIG. 4A, can advantageously prevent a local temperature increase.

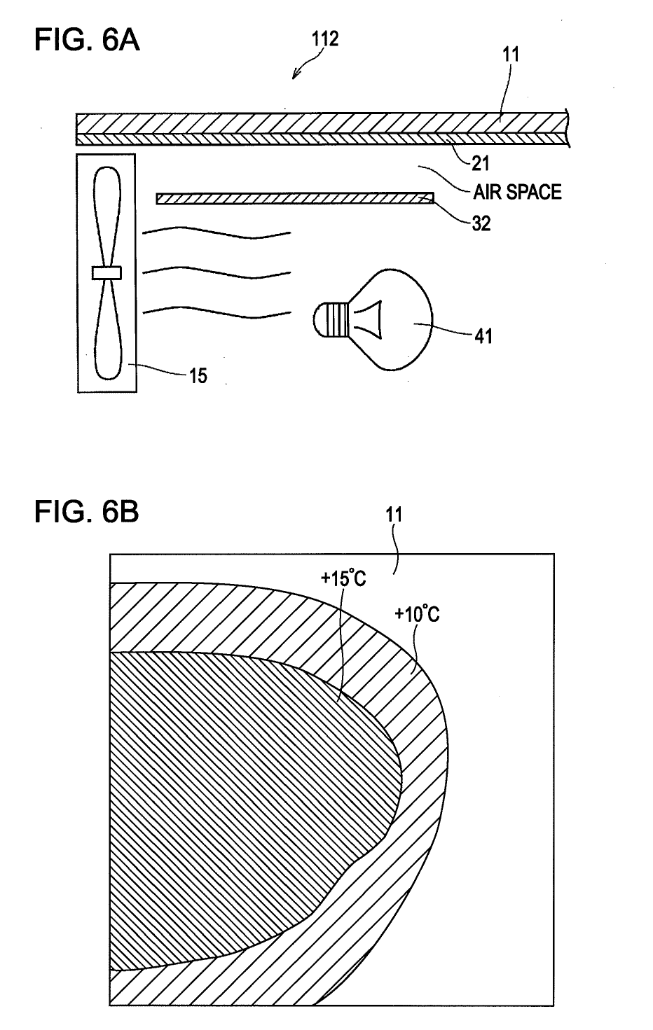

FIG. 6A is a cross sectional view of a heat dissipating device (made up of a magnesium enclosure 11, a graphite sheet 21, and aluminum sheet metal 32) provided in a liquid crystal projector 112 of a comparative example 2, and FIG. 6B is a thermal distribution diagram corresponding thereto.

As shown in FIG. 6A, the liquid crystal projector 112 of the comparative example 2 includes a lamp unit 41, the aluminum sheet metal 32, the graphite sheet 21, the magnesium enclosure 11, and an exhaust fan 15, which are identical to those included in the liquid crystal projector 10 of the embodiment of the present invention shown in FIG. 4A.

The liquid crystal projector 112 of the comparative example 2 shown in FIG. 6A, however, fails to include the melamine foam 31 included in the liquid crystal projector 10 of the embodiment of the present invention shown in FIG. 4A. In the liquid crystal projector 112 of the comparative example 2, there is an air space in place of the melamine foam 31 (i.e., between the aluminum sheet metal 32 and the graphite sheet 21).

With the liquid crystal projector 112 of the comparative example 2 having the above-described structure, heat generated in the lamp unit 41 is transmitted to the air space between the aluminum sheet metal 32 and the graphite sheet 21. The air space on the inner side of the graphite sheet 21 becomes hot, and the heat received by the graphite sheet 21 from the high-temperature air space is diffused from the graphite sheet 21 into the entirety of the magnesium enclosure 11. As a result, the magnesium enclosure 11 suffers a temperature increase of 15° C. or more over a wide area, as shown in FIG. 6B. Accordingly, it can be said that the sandwich structure made up of the aluminum sheet metal 32, the melamine foam 31, and the graphite sheet 21, with no air space included, as in the liquid crystal projector 10 of the embodiment of the present invention shown in FIG. 4A, can advantageously prevent an overall temperature increase.

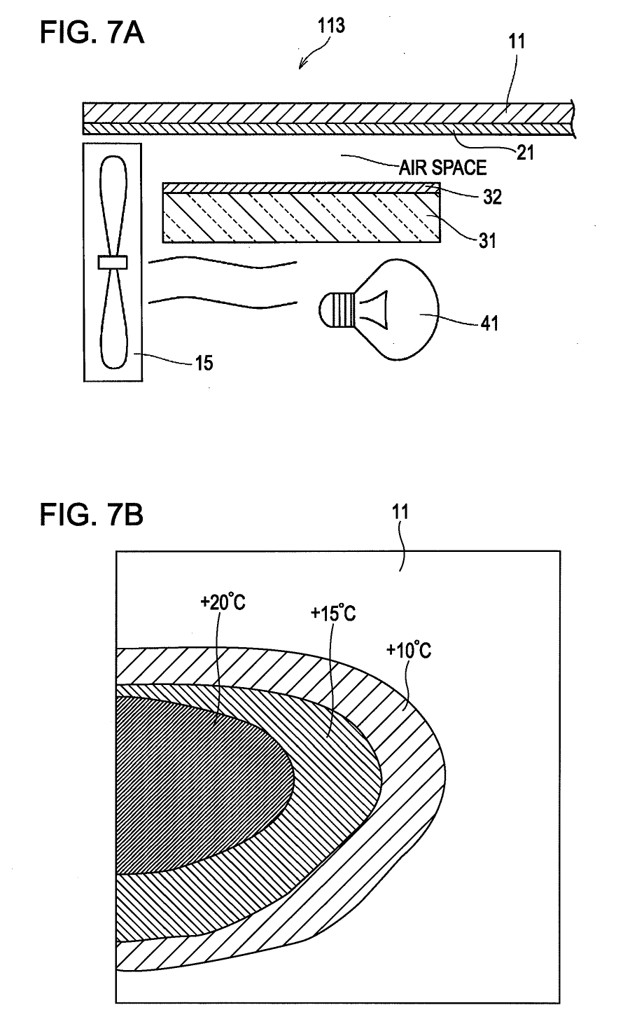

FIG. 7A is a cross sectional view of a heat dissipating device (made up of a magnesium enclosure 11, a graphite sheet 21, aluminum sheet metal 32, and melamine foam 31) provided in a liquid crystal projector 113 of a comparative example 3, and FIG. 7B is a thermal distribution diagram corresponding thereto.

As shown in FIG. 7A, the liquid crystal projector 113 of the comparative example 3 includes a lamp unit 41, the melamine foam 31, the aluminum sheet metal 32, the graphite sheet 21, the magnesium enclosure 11, and an exhaust fan 15, which are identical to those included in the liquid crystal projector 10 of the embodiment of the present invention shown in FIG. 4A.

In the liquid crystal projector 113 of the comparative example 3 shown in FIG. 7A, however, the melamine foam 31, which had been arranged between the aluminum sheet metal 32 and the graphite sheet 21 in the liquid crystal projector 10 of the embodiment of the present invention shown in FIG. 4A, is provided between the lamp unit 41 and the aluminum sheet metal 32, and there is an air space between the aluminum sheet metal 32 and the graphite sheet 21.

With the liquid crystal projector 113 of the comparative example 3 having the above-described structure, heat generated in the lamp unit 41 is transmitted to the melamine foam 31 which is arranged immediately above the lamp unit 41. This increases the amount of the heat that is not absorbed in the melamine foam 31, and such heat is transmitted via the aluminum sheet metal 32 to the air space. The air space on the inner side of the graphite sheet 21 becomes hot, and thus, the magnesium enclosure 11 becomes hot with the heat transmitted via the graphite sheet 21. As a result, the magnesium enclosure 11 suffers a local temperature increase of 20° C. or more, as shown in FIG. 7B. Accordingly, it can be said that the sandwich structure made up of the aluminum sheet metal 32, the melamine foam 31, and the graphite sheet 21, with no air space included, as in the liquid crystal projector 10 of the embodiment of the present invention shown in FIG. 4A, can advantageously prevent a local temperature increase.

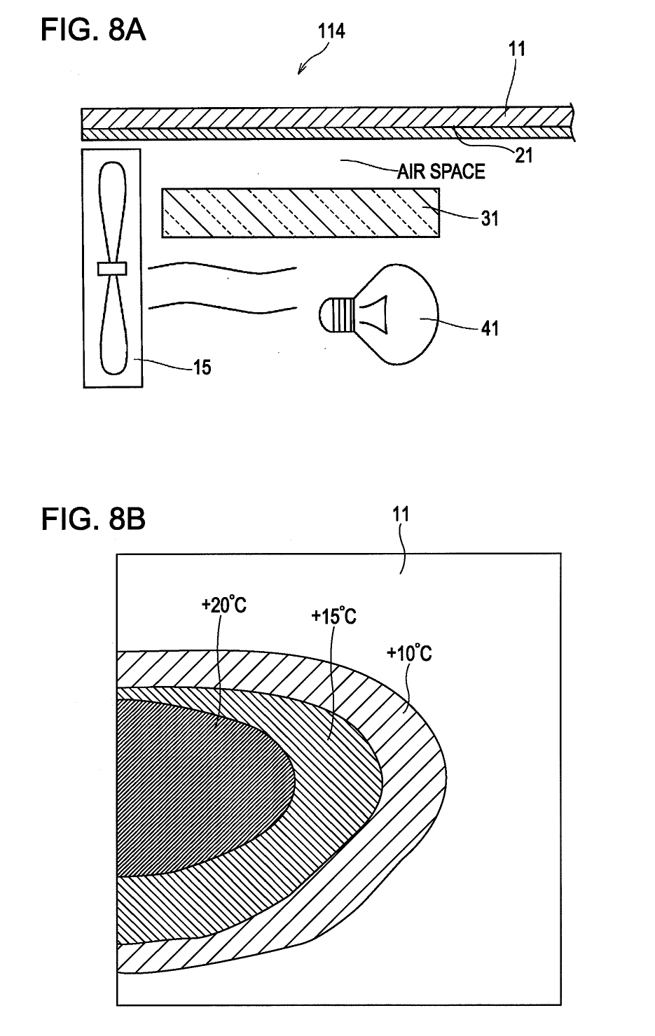

FIG. 8A is a cross sectional view of a heat dissipating device (made up of a magnesium enclosure 11, a graphite sheet 21, and melamine foam 31) provided in a liquid crystal projector 114 of a comparative example 4, and FIG. 8B is a thermal distribution diagram corresponding thereto.

As shown in FIG. 8A, the liquid crystal projector 114 of the comparative example 4 includes a lamp unit 41, the melamine foam 31, the graphite sheet 21, the magnesium enclosure 11, and an exhaust fan 15, which are identical to those included in the liquid crystal projector 10 of the embodiment of the present invention shown in FIG. 4A.

The liquid crystal projector 114 of the comparative example 4 shown in FIG. 8A, however, fails to include the aluminum sheet metal 32 included in the liquid crystal projector 10 of the embodiment of the present invention shown in FIG. 4A. Further, the melamine foam 31 is arranged immediately above the lamp unit 41, as in the liquid crystal projector 113 of the comparative example 3 shown in FIG. 7A. In the liquid crystal projector 114 of the comparative example 4, there is an air space between the melamine foam 31 and the graphite sheet 21.

With the liquid crystal projector 114 of the comparative example 4 having the above-described structure, heat generated in the lamp unit 41 is transmitted to the melamine foam 31 which is arranged close to the lamp unit 41. This increases the amount of the heat that is not absorbed by the melamine foam 31, and such heat is transmitted to the air space above the melamine foam 31. The air space on the inner side of the graphite sheet 21 becomes hot, and thus, the magnesium enclosure 11 becomes hot with the heat transmitted via the graphite sheet 21. As a result, the magnesium enclosure 11 suffers a local temperature increase of 20° C. or more, as shown in FIG. 8B. Accordingly, it can be said that the sandwich structure made up of the aluminum sheet metal 32, the melamine foam 31, and the graphite sheet 21, with no air space included, as in the liquid crystal projector 10 of the embodiment of the present invention shown in FIG. 4A, can advantageously prevent a local temperature increase.

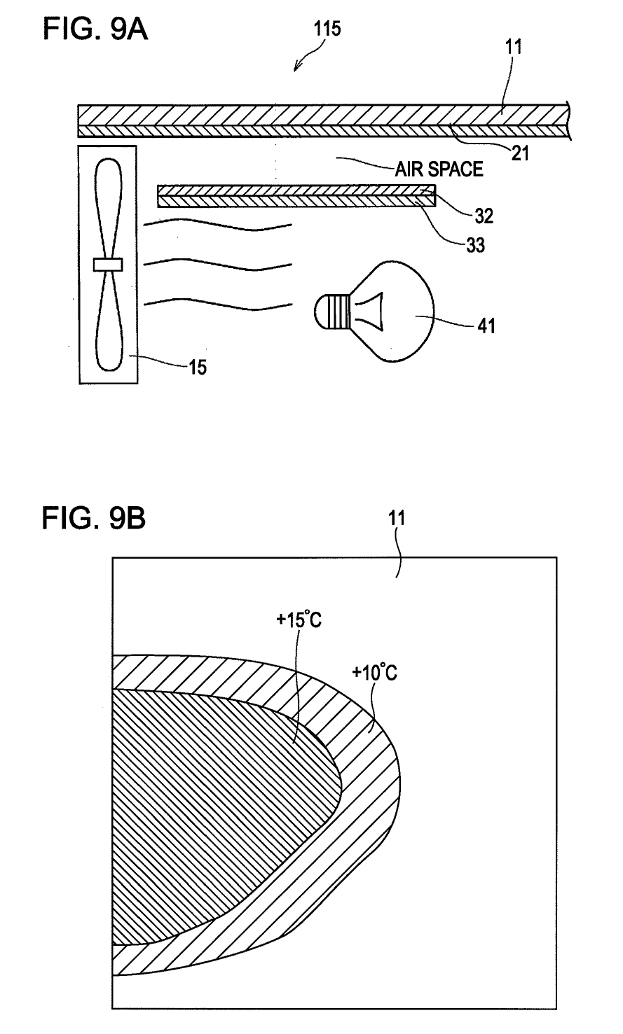

FIG. 9A is a cross sectional view of a heat dissipating device (made up of a magnesium enclosure 11, a graphite sheet 21, aluminum sheet metal 32, and a graphite sheet 33) provided in a liquid crystal projector 115 of a comparative example 5, and FIG. 9B is a thermal distribution diagram corresponding thereto.

As shown in FIG. 9A, the liquid crystal projector 115 of the comparative example 5 includes a lamp unit 41, the aluminum sheet metal 32, the graphite sheet 21, the magnesium enclosure 11, and an exhaust fan 15, which are identical to those included in the liquid crystal projector 10 of the embodiment of the present invention shown in FIG. 4A.

The liquid crystal projector 115 of the comparative example 5 shown in FIG. 9A, however, fails to include the melamine foam 31 included in the liquid crystal projector 10 of the embodiment of the present invention shown in FIG. 4A. On the other hand, the graphite sheet 33 identical in terms of thickness and size to the aluminum sheet metal 32 is additionally arranged between the lamp unit 41 and the aluminum sheet metal 32. In the liquid crystal projector 115 of the comparative example 5, there is an air space between the aluminum sheet metal 32 and the graphite sheet 21.

With the liquid crystal projector 115 of the comparative example 5 having the above-described structure, heat generated in the lamp unit 41 is transmitted to the air space between the aluminum sheet metal 32 and the graphite sheet 21, despite the arrangement of the graphite sheet 33. The air space on the inner side of the graphite sheet 21 becomes hot, and the heat that the graphite sheet 21 has received from the high-temperature air space is diffused from the graphite sheet 21 into the entirety of the magnesium enclosure 11. As a result, the magnesium enclosure 11 suffers a temperature increase of 15° C. or more over a wide area, as shown in FIG. 9B. Accordingly, it can be said that the sandwich structure made up of the aluminum sheet metal 32, the melamine foam 31, and the graphite sheet 21, with no air space included, as in the liquid crystal projector 10 of the embodiment of the present invention shown in FIG. 4A, can advantageously prevent an overall temperature increase.

The present application contains subject matter related to that disclosed in Japanese Priority Patent Application JP 2008-314444 filed in the Japan Patent Office on Dec. 10, 2008, the entire content of which is hereby incorporated by reference.

While the embodiment of the present invention has been described above, it should be understood that various modifications may occur without being restricted by the embodiment. For example, in the above embodiment, the liquid crystal projector 10 which is a projection display apparatus has been given as an example of the electronic apparatus, and a local temperature increase of the magnesium enclosure 11 due to heat generated in the lamp unit 41 has been prevented. Alternatively, it may be configured to prevent a local temperature increase due to various components including the light valve 42 which become hot. Furthermore, the present invention may be applied, not only to the liquid crystal projector, but also to various electronic apparatuses including a liquid crystal display and a notebook-sized personal computer, and may be applied to prevent a local temperature increase due to any of components including a backlight and a CPU which become hot in such electronic apparatuses.

What is claimed is:

1. A heat dissipating device for an electronic apparatus, the heat dissipating device comprising:
an enclosure configured to house a component of an electronic apparatus, the component becoming hot when the electronic apparatus is in use, the enclosure being made of a heat conductive material capable of dissipating heat in the enclosure to the outside;
a heat receiving member provided between the component and the enclosure and capable of receiving heat from the component and transferring the received heat;
a heat insulating member provided in contact with a side of the heat receiving member opposite from the component, the heat insulating member being configured to prevent transmission of the heat received by the heat receiving member; and
a heat diffusing member provided between the heat insulating member and the enclosure so as to contact both the heat insulating member and the enclosure, the heat diffusing member being capable of receiving heat from the heat insulating member and diffusing the received heat into the enclosure.

2. The heat dissipating device for an electronic apparatus according to claim 1, wherein
the heat receiving member and the heat insulating member are arranged so as to face the component, and
the heat diffusing member is arranged to cover an area wider than an area covered by the heat receiving member and an area covered by the heat insulating member.

3. The heat dissipating device for an electronic apparatus according to claim 1, wherein
each of the heat receiving member, the heat insulating member, and the heat diffusing member has a flat shape, and
the heat insulating member has a thickness greater than a thickness of the heat receiving member and a thickness of the heat diffusing member.

4. An electronic apparatus comprising:
a component which becomes hot when in use;
an enclosure configured to house the component, the enclosure being made of a heat conductive material capable of dissipating heat in the enclosure to the outside;
a heat receiving member provided between the component and the enclosure and capable of receiving heat from the component and transferring the received heat;
a heat insulating member provided in contact with a side of the heat receiving member opposite from the component, the heat insulating member being configured to prevent transmission of the heat received by the heat receiving member; and
a heat diffusing member provided between the heat insulating member and the enclosure so as to contact both the heat insulating member and the enclosure, the heat diffusing member being capable of receiving heat from the heat insulating member and diffusing the received heat into the enclosure.

5. The electronic apparatus according to claim 4, further comprising:
a light source configured to emit light for projecting an image;
a light valve configured to modulate the light emitted from the light source; and
a projection lens configured to project an image which is obtained by irradiating the light valve with light;
the heat receiving member being arranged so as to face the light source.

6. The electronic apparatus according to claim 4, further comprising an exhaust fan configured to exhaust air between the component and the heat receiving member to the outside of the enclosure.
